(19) United States
(12) Patent Application Publication
(10) Pub. No.: US 2016/0173046 A1
(43) Pub. Date: Jun. 16, 2016

(54) METHOD, HEAD UNIT AND COMPUTER-READABLE RECORDING MEDIUM FOR ADJUSTING BLUETOOTH AUDIO VOLUME

(71) Applicant: Hyundai Motor Company, Seoul (KR)

(72) Inventor: Seung Woo Lee, Gumi (KR)

(21) Appl. No.: 14/716,346

(22) Filed: May 19, 2015

(30) Foreign Application Priority Data
Dec. 11, 2014 (KR) 10-2014-0178283

(51) Int. Cl. H03G 3/20

(52) U.S. Cl. CPC H03G 3/20

(57) ABSTRACT

A head unit includes a microcomputer storing last volume information corresponding to a finally adjusted volume of each of at least one mobile terminal. The microcomputer outputs an audio stream having a volume value adjusted based on the last volume information when a first paired mobile terminal of the at least one mobile terminal transmits the audio stream.

### CROSS-REFERENCE TO RELATED APPLICATION

This application claims priority to and the benefit of Korean Patent Application No. 10-2014-0178283, filed on Dec. 11, 2014, which is hereby incorporated by reference as if fully set forth herein.

### BACKGROUND

1. Technical Field

The present disclosure relates to a method, a head unit and a computer-readable recording medium for adjusting a Bluetooth audio volume, and more particularly, to a method, a head unit and a computer-readable recording medium for adjusting a Bluetooth audio volume of audio transmitted between a mobile terminal and the head unit to a value suitable for the head unit.

2. Discussion of the Related Art

Recently, head units have been widely utilized for multimedia systems in vehicles. The head unit refers to a multimedia system in which audio (such as a radio, a compact disc (CD) or the like), video (such as a digital versatile disc (DVD) or the like), and a navigation system (such as a destination guide function and the like) are integrated. Conventional head units have provided a touch interface environment such that the above-described multimedia devices are easily operated. Additionally, conventional head units have been capable of being connected to an external device, e.g., a portable playback device (such as a mobile terminal, smartphone, etc.), a portable multimedia player (PDP), a handset, an MPEG Audio Layer-3 (MP3) player, a personal digital assistant (PDA), or the like.

For example, conventional head units have been able to download a Bluetooth audio stream from the mobile terminal and reproduce the downloaded stream while connected to the mobile terminal through Bluetooth communication. However, when Bluetooth audio streaming is used, conventional head units suffer from a problem in that a difference in volume between varying mobile terminals occur since each mobile terminal may separately adjust its respective volume.

### SUMMARY

Accordingly, the present disclosure is directed to a method, a head unit and a computer-readable recording medium for adjusting a Bluetooth audio volume which substantially obviate one or more problems due to limitations and disadvantages of the related art. According to the present disclosure, it is possible to overcome a difference in volume of Bluetooth audio streaming between a mobile terminal and the head unit, and manage a volume suitable for paired mobile terminals.

To achieve these objects and other advantages and in accordance with the purpose of the present disclosure, as embodied and broadly described herein, a head unit includes a microcomputer storing last volume information corresponding to a finally adjusted volume of each of at least one mobile terminal. The microcomputer outputs an audio stream having a volume value adjusted based the last volume information when a first paired mobile terminal of the at least one mobile terminal transmits the audio stream.

The microcomputer may output the audio stream having the adjusted volume value by controlling an amplifier. The microcomputer may output the audio stream in real-time.

Furthermore, according to embodiments of the present disclosure, a method of adjusting an audio volume of a head unit includes: storing, by a microcomputer, last volume information corresponding to a finally adjusted volume of each of at least one mobile terminal, receiving, at the microcomputer, an audio stream transmitted from a first paired mobile terminal of the at least one mobile terminal, adjusting a volume value of the received audio stream based on the stored last volume information, and outputting, by the microcomputer, the audio stream having the adjusted volume value.

The outputting of the audio stream having the adjusted volume value may include outputting the audio stream by the microcomputer controlling an amplifier. The outputting may include outputting the audio stream in real-time by controlling an amplifier.

Furthermore, according to embodiments of the present disclosure, a head unit includes a microcomputer storing a maximum audio volume value of at least one mobile terminal. The microcomputer compensates for a volume value of an audio stream transmitted from a first paired mobile terminal of the at least one mobile terminal based on the maximum audio volume value.

The microcomputer may output audio volume information calculated by adding a volume compensation value obtained by the compensation for the volume value of the transmitted audio stream to the volume value of the audio stream.

The microcomputer may output the audio volume information by controlling an amplifier. The microcomputer may output the audio volume information in real-time by controlling the amplifier.

Furthermore, according to embodiments of the present disclosure, a method of adjusting an audio volume of a head unit includes: storing, by a microcomputer, a maximum audio volume value of at least one mobile terminal, receiving, at the microcomputer, an audio stream transmitted from a first paired mobile terminal of the at least one mobile terminal, compensating, by the microcomputer, for a volume value of the transmitted audio stream based on the stored maximum audio volume value, and outputting, by the microcomputer, audio volume information obtained by the compensating for the volume value of the transmitted audio stream.

The compensating for the volume value of the audio stream may include generating, by the microcomputer, the audio volume information calculated by adding a volume compensation value obtained by the compensation for the volume value of the audio stream to the volume value of the audio stream.

The outputting may include outputting of the audio volume information the generated audio volume information by the microcomputer controlling an amplifier. The outputting of the audio volume information may include outputting the audio volume information in real-time by the microcomputer controlling the amplifier.

Furthermore, according to embodiments of the present disclosure, a head unit includes a microcomputer storing a maximum audio volume value of at least one mobile terminal, wherein the microcomputer generates audio volume compensation information by compensating for a volume value of an audio stream transmitted from a first paired mobile terminal of the at least one mobile terminal based on the maximum audio volume value, transmits the generated audio volume compensation information to the first mobile terminal, and then receives an audio stream adjusted based on the audio volume compensation information as a response to the transmission of the audio stream.

The microcomputer may transmit, to the first mobile terminal, the audio volume compensation information calculated by adding a volume compensation value obtained by the compensation for the volume value of the audio stream to the volume value of the audio stream.

The microcomputer may output the audio stream by controlling an amplifier. The microcomputer may output the audio stream in real-time by controlling the amplifier.

Furthermore, according to embodiments of the present disclosure, a method of adjusting an audio volume of a head unit includes: storing, by a microcomputer, a maximum audio volume value of at least one mobile terminal, receiving, at the microcomputer, an audio stream transmitted from a first paired mobile terminal of the at least one mobile terminal, generating audio volume compensation information by compensating for a volume value of the audio stream based on the maximum audio volume value, transmitting the generated audio volume compensation information to the first mobile terminal, receiving, at the microcomputer, an audio stream adjusted based on the transmitted audio volume compensation information, and outputting, by the microcomputer, the received audio stream.

The transmitting of the generated audio volume compensation information may include transmitting, by the microcomputer, the audio volume compensation information calculated by adding a volume compensation value obtained by the compensation for the volume value of the audio stream to the volume value of the audio stream to the first mobile terminal.

The outputting may include outputting the audio stream by the microcomputer controlling an amplifier. The outputting may include outputting the audio stream in real-time by the microcomputer controlling the amplifier.

One or more of the above referenced-methods may be executed by a non-transitory computer-readable recording medium.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain the principle of the present disclosure. In the drawings:

FIG. 1 is a block diagram illustrating a head unit 100 of a vehicle according to embodiments of the present disclosure;

FIG. 2 is a flowchart illustrating an audio volume adjustment method 5100 of the head unit 100 according to embodiments of the present disclosure;

FIG. 3 is a block diagram illustrating a head unit 200 of a vehicle according to embodiments of the present disclosure;

FIG. 4 is a flowchart illustrating an audio volume adjustment method 5200 of the head unit 200 according to embodiments of the present disclosure;

FIG. 5 is a block diagram illustrating a head unit 300 of a vehicle according to embodiments of the present disclosure; and

FIG. 6 is a flowchart illustrating an audio volume adjustment method 5300 of the head unit 300 according to embodiments of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

Additionally, it is understood that one or more of the below methods, or aspects thereof, may be executed by at least one microcomputer. The term “microcomputer” may refer to a hardware device that includes a memory and a processor. The memory is configured to store program instructions, and the processor is specifically programmed to execute the program instructions to perform one or more processes which are described further below. Moreover, it is understood that the below methods may be executed by an apparatus comprising the microcomputer in conjunction with one or more other components, as would be appreciated by a person of ordinary skill in the art.

Furthermore, the microcomputer of the present disclosure may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

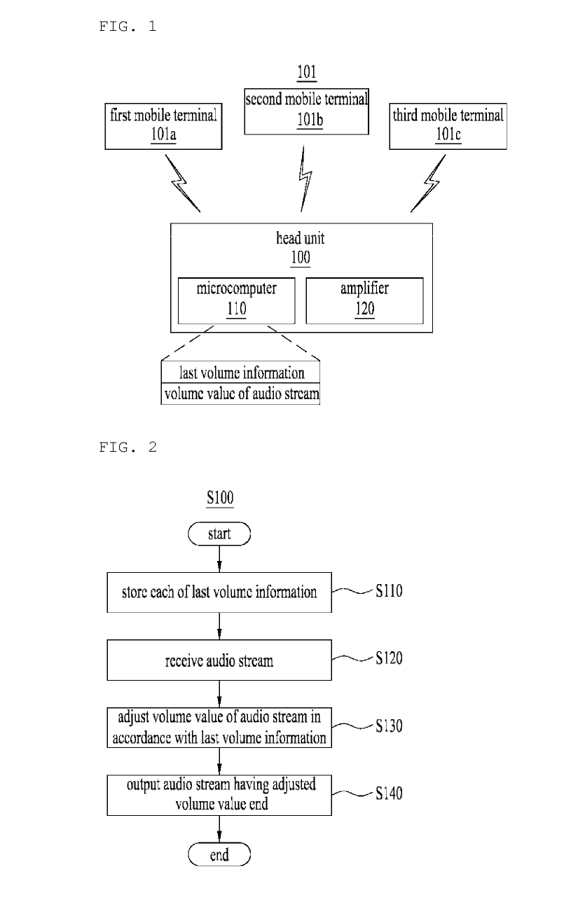

Referring now to the disclosed embodiments, FIG. 1 illustrates a head unit 100 of a vehicle according to embodiments of the present disclosure. As shown in FIG. 1, the head unit 100 receives last volume information corresponding to a finally adjusted volume from each of at least one mobile terminal 101. For example, each of the last volume information is received such that first last volume information is received from a first mobile terminal 101a among the at least one mobile terminal 101, second last volume information is received from a second mobile terminal 101b among the at least one mobile terminal 101, and third last volume information is received from a third mobile terminal 101c among the at least one mobile terminal 101. In this instance, the first last volume information to the third last volume information have different volume values as described above. The last volume information including each of the volume values is stored in a microcomputer 110.

The microcomputer 110 that stores the last volume information is a microcomputer configured on an integrated circuit (IC) chip. The microcomputer 110 may manage various processes such as a process of controlling Bluetooth connection and the like in addition to the amplifier 120 to be described below, a process of controlling data exchanged in the head unit 100, a process of storing processed data, and the like.

When the last volume information is stored in the microcomputer 110, and then the head unit 100 is paired with the mobile terminal 101, for example, the first mobile terminal 101a through Bluetooth communication, the head unit 100 according to the present embodiment receives a Bluetooth audio stream from the paired first mobile terminal 101a, and then outputs the information in accordance with the last volume information stored in the microcomputer 110. For example, it is presumed that the last volume information of the first mobile terminal 101a stored in the microcomputer 110 has a volume value of 10 dB. In this case, when the audio stream transmitted from the first mobile terminal 101a has a volume value of 5 dB, the microcomputer 110 recognizing the received audio stream having the volume value of 5 dB may convert the volume value of 5 dB of the audio stream into the volume value of the last volume information corresponding to 10 dB and output the audio stream having the converted volume value. Similarly, when another mobile terminal 101 is paired with the head unit 100 through Bluetooth communication, the microcomputer 110 may convert a volume value of an audio stream transmitted from the current mobile terminal 100 into a volume value of the previously stored last volume information and output the audio stream having the converted volume value.

The microcomputer 110 may output an audio stream, which is output in accordance with the last volume information, by controlling the amplifier 120. In other words, the microcomputer 110 transmits an audio stream corresponding to the last volume information of the first mobile terminal 101a to the amplifier 120, and then outputs the audio stream by controlling the amplifier 120. This output operation may be performed in real-time under control of the microcomputer 110. In this way, a driver in a vehicle may enjoy sound having a volume adjusted to an optimal value desired by the driver without separately adjusting a volume of an audio stream transmitted from the first mobile terminal 101a connected through Bluetooth communication.

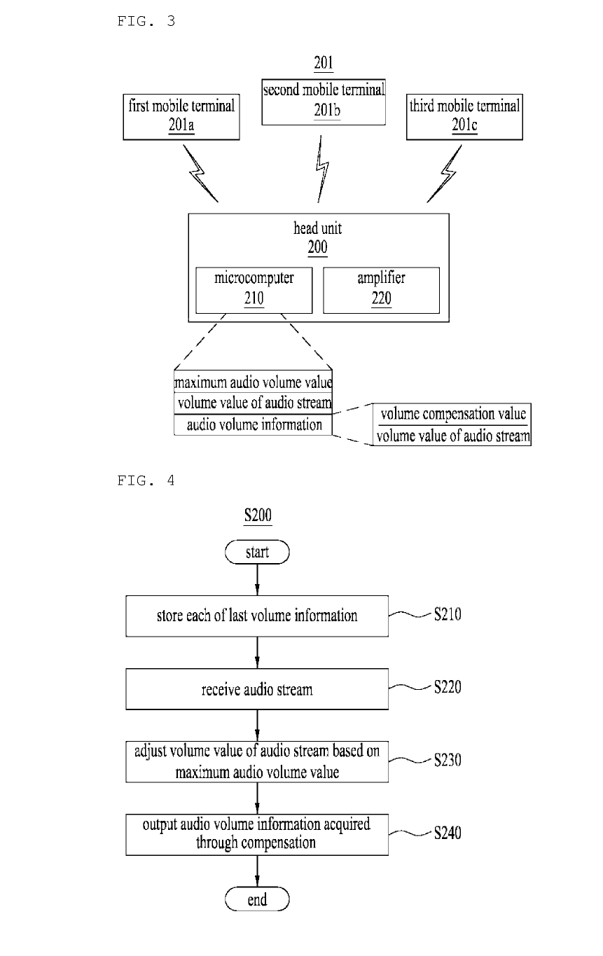

FIG. 2 illustrates an audio volume adjustment method 5100 of the head unit 100 according to embodiments of the present disclosure. Referring to FIG. 2, the audio volume adjustment method 5100 of the head unit 100 may include step S110 to step S140 to optimize a volume of a Bluetooth stream.

First, in step S110, last volume information corresponding to a finally adjusted volume of the at least one mobile terminal 101 is received by the head unit 100. For example, each of the last volume information is received such that first last volume information is received by the head unit 100 from the first mobile terminal 101a among the at least one mobile terminal 101, second last volume information is received by the head unit 100 from the second mobile terminal 101b among the at least one mobile terminal 101, and third last volume information is received by the head unit 100 from the third mobile terminal 101c among the at least one mobile terminal 101.

In this instance, the first last volume information to the third last volume information may have different volume values. The last volume information including each of the volume values is stored in the microcomputer 110 of the head unit 100. As described above, the last volume information stored in the microcomputer 110 refers to an audio stream, a volume of which is adjusted to a different value for each of the at least one mobile terminal 101.

Thereafter, in step S120, an audio stream transmitted from the first paired mobile terminal 101a among the at least one mobile terminal 101 is received by the microcomputer 110. In this instance, the received audio stream has a volume value of a current audio stream played back in the first mobile terminal 101a.

Thereafter, in step S130, the audio stream received in step S120 is adjusted in accordance with the last volume information stored in the microcomputer 110. The adjustment indicates that a volume value of the audio stream reproduced in the first mobile terminal 101a is converted into a value of the last volume information of the first mobile terminal 101a. For example, it is presumed that the last volume information of the first mobile terminal 101a stored in the microcomputer 110 has a volume value of 10 dB. In this case, when the audio stream transmitted from the first mobile terminal 101a has a volume value of 5 dB, the microcomputer 110 recognizing the received audio stream having the volume value of 5 dB converts the audio stream having the volume value of 5 dB into a volume value of the last volume information having the volume value of 10 dB. Volumes of the other terminals 101b and 101c may be similarly adjusted.

Thereafter, in step S140, the microcomputer 110 outputs the last volume information adjusted in S130. It is preferable that the microcomputer 110 output an audio stream, which is output in accordance with the last volume information, by controlling the amplifier 120. In other words, the microcomputer 110 transmits the audio stream adjusted in accordance with the last volume information of the first mobile terminal 101a to the amplifier 120, and then outputs the audio stream by controlling the amplifier 120. This output operation may be performed in real-time under control of the microcomputer 110. In this way, a driver in a vehicle may enjoy sound having a volume adjusted to an optimal value desired by the driver without separately adjusting a volume of an audio stream transmitted from the first mobile terminal 101a connected through Bluetooth communication.

FIG. 3 illustrates a head unit 200 of a vehicle according to embodiments of the present disclosure. Referring to FIG. 3, the head unit 200 of the vehicle receives a maximum audio volume value included in each of at least one mobile terminal 201 from each of the at least one mobile terminal 201. The maximum audio volume value refers to a volume value of an audio volume set to a maximum value for each of the at least one mobile terminal 201. The maximum audio volume value received by the head unit 200 may be stored in a microcomputer 210.

The microcomputer 210 that stores the maximum audio volume value is a microcomputer configured on an IC chip. The microcomputer 210 may manage various processes such as a process of controlling Bluetooth connection and the like in addition to an amplifier 220 to be described below, a process of controlling data exchanged in the head unit 200, a process of storing processed data, and the like.

When the maximum audio volume value is stored in the microcomputer 210, and then the head unit 200 is paired with the mobile terminal 201, for example the first mobile terminal 201a, through Bluetooth communication, the head unit 200 receives a Bluetooth audio stream from the first paired mobile terminal 201a, and then compensates for a volume value of the audio stream based on the maximum audio volume value stored in the microcomputer 210. For example, it is presumed that the maximum audio volume value of the first mobile terminal 201a stored in the microcomputer 210 is 15 dB. In this case, when the audio stream transmitted from the first mobile terminal 201a has a volume value of 5 dB, the microcomputer 210 recognizing the received audio stream having the volume value of 5 dB may compensate for the volume value based on the maximum audio volume value of 15 dB to obtain, for example, about 20 dB. A level of compensation may be frequently changed by a user.

Hereinafter, the volume value of 20 dB is referred to as a “volume compensation value”. In this case, the microcomputer 210 may output (e.g., generate) audio volume information obtained by adding the volume compensation value obtained through compensation based on the maximum audio volume value to the volume value of the audio stream. For example, the microcomputer 210 may output audio volume information of 25 dB obtained by adding the volume compensation value of 20 dB obtained based on the maximum audio volume value to the volume value of the audio stream of 5 dB.

Similarly, when the other mobile terminals 201b and 201c are paired with the head unit 200 through Bluetooth communication performed therebetween, the microcomputer 210 may compensate for a volume value of an audio stream currently transmitted from each of the mobile terminals 201b and 201c by a previously stored maximum audio volume value, thereby outputting an audio stream corresponding to audio volume information obtained by adding a volume compensation value obtained through compensation based on the maximum audio volume value to the value of the audio stream for each of the mobile terminals 201b and 201c.

In this way, the microcomputer 210 may output the audio stream, which is output in accordance with the audio volume information, by controlling the amplifier 220. In other words, the microcomputer 210 transmits the audio stream adjusted in accordance with the audio volume information of the first mobile terminal 201a to the amplifier 220, and then outputs the audio stream by controlling the amplifier 220. This output operation may be performed in real-time under control of the microcomputer 210. Accordingly, a driver in a vehicle may enjoy sound having a volume adjusted to an optimal value desired by the driver without separately adjusting a volume of an audio stream transmitted from the first mobile terminal 201a connected through Bluetooth communication.

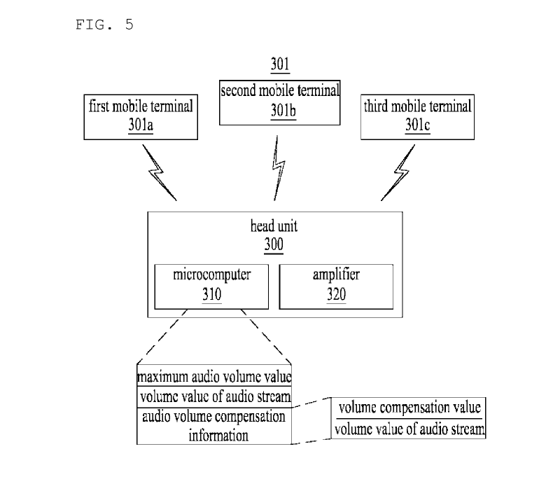

FIG. 4 illustrates an audio volume adjustment method 5200 of the head unit 200 according to embodiments of the present disclosure. Referring to FIG. 4, the audio volume adjustment method 5200 of the head unit 200 may include step S210 to step S240 to optimize a volume of a Bluetooth stream.

First, in step S210, a maximum audio volume value included in at least one mobile terminal 201 is received by the head unit 200. The maximum audio volume value may be different for each of the at least one mobile terminal 201. For example, the head unit 200 may receive a first maximum audio volume value from the first mobile terminal 201a among the at least one mobile terminal 201, receive a second maximum audio volume value from the second mobile terminal 201b among the at least one mobile terminal 201, and receive a third maximum audio volume value from the third mobile terminal 201c among the at least one mobile terminal 201.

Thereafter, in step S220, an audio stream transmitted from the first paired mobile terminal 201a among the at least one mobile terminal 201 is received by the microcomputer 210. In this instance, the received audio stream has a volume value of an audio stream reproduced in the first mobile terminal 201a.

Thereafter, in step S230, a volume value of the audio stream received in S220 is compensated by the microcomputer 210 based on the maximum audio volume value stored in the microcomputer 210. For example, it is presumed that the maximum audio volume value of the first mobile terminal 201a stored in the microcomputer 210 is 15 dB. In this case, when the audio stream transmitted from the first mobile terminal 201a has a volume value of 5 dB, the microcomputer 210 recognizing the received audio stream having the volume value of 5 dB may compensate for the audio stream based on the maximum audio volume value of 15 dB to obtain, for example, about 20 dB.

Hereinafter, the volume value of 20 dB is referred to as a “volume compensation value”. In this case, in step S240, the microcomputer 210 outputs audio volume information obtained by adding the volume compensation value obtained through compensation based on the maximum audio volume value to the volume value of the audio stream. For example, audio volume information of 25 dB obtained by adding the volume compensation value of 20 dB obtained based on the maximum audio volume value to the volume value of the audio stream of 5 dB may be generated by the microcomputer 210. Similarly, when the other mobile terminals 201b and 201c are paired with the head unit 200 through Bluetooth communication performed therebetween, the microcomputer 210 may compensate for a volume value of an audio stream currently transmitted from each of the mobile terminals 201b and 201c by a previously stored maximum audio volume value, thereby generating an audio stream corresponding to audio volume information obtained by adding a volume compensation value obtained through compensation based on the maximum audio volume value to the volume value of the audio stream for each of the mobile terminals 201b and 201c in step S240.

Lastly, in step S240, the audio stream, which is output in accordance with the audio volume information generated in step S230, may be output by controlling the amplifier 220. In other words, in step S240, the audio stream corresponding to the audio volume information of the first mobile terminal 201a is transmitted to the amplifier 220 by the microcomputer 210, and then the audio stream is output by controlling the amplifier 220. This output operation may be performed in real-time under control of the microcomputer 210. Accordingly, a driver in a vehicle may enjoy sound having a volume adjusted to an optimal value desired by the driver without separately adjusting a volume of an audio stream transmitted from the first mobile terminal 201a connected through Bluetooth communication.

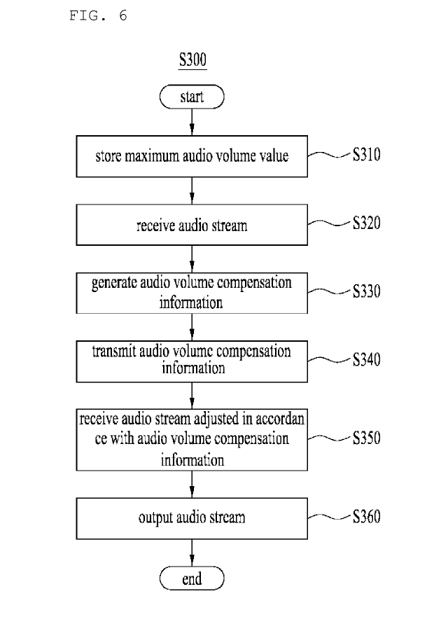

FIG. 5 illustrates a head unit 300 of a vehicle according to embodiments of the present disclosure. Referring to FIG. 5, the head unit 300 of the vehicle receives a maximum audio volume value included in each of at least one mobile terminal 301 from each of the at least one mobile terminal 301. For example, the maximum audio volume value is received such that a first maximum audio volume value is received from a first mobile terminal 301a among the at least one mobile terminal 301, a second maximum audio volume value is received from a second mobile terminal 301b among the at least one mobile terminal 301, and a third maximum audio volume value is received from a third mobile terminal 301c among the at least one mobile terminal 301.

The maximum audio volume value refers to a volume value obtained by setting an audio volume to a maximum value for each of the at least one mobile terminal 301. The maximum audio volume value received by the head unit 300 may be stored in a microcomputer 310. The microcomputer 310 that stores the maximum audio volume value is a microcomputer configured on an IC chip. The microcomputer 310 may manage various processes such as a process of controlling Bluetooth connection and the like in addition to an amplifier 320 to be described below, a process of controlling data exchanged in the head unit 300, a process of storing processed data, and the like.

When the maximum audio volume value is stored in the microcomputer 310, and then the head unit 300 is paired with the mobile terminal 301, for example, the first mobile terminal 301a through Bluetooth communication, the head unit 300 receives a Bluetooth audio stream from the first paired mobile terminal 301a, and then compensates for a volume value of the audio stream based on the maximum audio volume value stored in the microcomputer 310. For example, it is presumed that the maximum audio volume value of the first mobile terminal 301a stored in the microcomputer 310 is 15 dB. In this case, when the audio stream transmitted from the first mobile terminal 301a has a volume value of 5 dB, the microcomputer 310 recognizing the received audio stream having the volume value of 5 dB may compensate for the audio stream based on the maximum audio volume value of 15 dB to obtain, for example, about 20 dB.

Hereinafter, the volume value of 20 dB generated through compensation is referred to as a “volume compensation value”. In this case, the microcomputer 310 generates audio volume compensation information obtained by adding the volume compensation value obtained through compensation based on the maximum audio volume value to the volume value of the audio stream.

Thereafter, the microcomputer 310 transmits the audio volume compensation information generated as described above to the first mobile terminal 301a, and then receives an audio stream corresponding to the audio volume compensation information from the first mobile terminal 301a in response to the transmission and outputs the audio stream. Similarly, when the other mobile terminals 301b and 301c are paired with the head unit 300 through Bluetooth communication performed therebetween, the microcomputer 310 may compensate for a volume value of an audio stream currently transmitted from each of the mobile terminals 301b and 301c by a value of the previously generated audio volume compensation information, thereby outputting an audio stream corresponding to the audio volume compensation information.

In this way, the microcomputer 310 may output the audio stream, which is output in accordance with the audio volume compensation information, by controlling the amplifier 320. In other words, the microcomputer 310 transmits the audio stream corresponding to the audio volume compensation information of the first mobile terminal 301a to the amplifier 320, and then outputs the audio stream by controlling the amplifier 320. This output operation may be performed in real-time under control of the microcomputer 310. Accordingly, a driver in a vehicle may enjoy sound having a volume adjusted to an optimal value desired by the driver without separately adjusting a volume since the audio stream transmitted from the first mobile terminal 301a connected through Bluetooth communication is adjusted in accordance with the audio volume compensation information and output by the head unit 300.

FIG. 6 illustrates an audio volume adjustment method 5300 of the head unit 300 according to embodiments of the present disclosure. Referring to FIG. 6, the audio volume adjustment method 5300 of the head unit 300 may include step S310 to step S360 to optimize a volume of a Bluetooth stream.

First, in step S310, a maximum audio volume value included in at least one mobile terminal 301 is received by the head unit 300. For example, the maximum audio volume value is received such that a first maximum audio volume value is received from the first mobile terminal 301a among the at least one mobile terminal 301, a second maximum audio volume value is received from the second mobile terminal 301b among the at least one mobile terminal 301, and a third maximum audio volume value is received from the third mobile terminal 301c among the at least one mobile terminal 301. The maximum audio volume value refers to a volume value obtained by setting an audio volume to a maximum value for each of the at least one mobile terminal 301. The maximum audio volume value received by the head unit 300 may be stored in the microcomputer 310.

When the maximum audio volume value is stored in the microcomputer 310, and then the head unit 300 is paired with the mobile terminal 301, for example the first mobile terminal 301a, through Bluetooth communication therebetween, the microcomputer 310 receives a Bluetooth audio stream from the paired first mobile terminal 301a in step S320. In this instance, the received audio stream has a volume value of an audio stream currently reproduced in the first mobile terminal 301a.

Thereafter, in step S330, the volume value of the audio stream described above in step S320 is compensated for based on the maximum audio volume value stored in the microcomputer 310. For example, it is presumed that the maximum audio volume value of the first mobile terminal 301a stored in the microcomputer 310 is 15 dB. In this case, when the audio stream transmitted from the first mobile terminal 301a has a volume value of 5 dB, the microcomputer 310 recognizing the received audio stream having the volume value of 5 dB may compensate for the volume value of the audio streaming volume information based on the maximum audio volume value of 15 dB to obtain, for example, about 20 dB. Hereinafter, the volume value of 20 dB generated through compensation is referred to as a “volume compensation value”. In this case, in step S330, audio volume compensation information is generated by adding the volume compensation value obtained through compensation based on the maximum audio volume value to the volume value of the audio stream.

Thereafter, in step S340, the microcomputer 310 transmits the audio volume compensation information generated in S330 to the first mobile terminal 301a. This transmission refers to control instruction transmission.

Thereafter, in step S350, the audio volume compensation information is transmitted to the first mobile terminal 301a, and then an audio stream corresponding to the audio volume compensation information is received from the first mobile terminal 301a in response to the transmission and output by the microcomputer 310. Similarly, operations in the above-described steps may be performed between each of the other mobile terminals 301b and 301c and the head unit 300.

Lastly, in step S360, the microcomputer 310 may output the audio stream corresponding to the audio volume compensation information output in step S350 described above by controlling the amplifier 320. In other words, in step S360, the microcomputer 310 transmits the audio stream corresponding to the audio volume compensation information of the first mobile terminal 301a to the amplifier 320, and then outputs the audio stream by controlling the amplifier 320. This output operation may be performed in real-time under control of the microcomputer 310. Accordingly, a driver in a vehicle may enjoy sound having a volume adjusted to an optimal value desired by the driver without separately adjusting a volume of the audio stream transmitted from the first mobile terminal 301a connected through Bluetooth communication.

The microcomputer 310 may output the audio stream, which is output in accordance with the audio volume compensation information, by controlling the amplifier 320. In other words, the microcomputer 310 transmits the audio stream corresponding to the audio volume compensation information of the first mobile terminal 301a to the amplifier 320, and then outputs the audio stream by controlling the amplifier 320. This output operation may be performed in real-time under control of the microcomputer 310. Accordingly, a driver in a vehicle may enjoy sound having a volume adjusted to an optimal value desired by the driver without separately adjusting a volume since the audio stream transmitted from the first mobile terminal 301a connected through Bluetooth communication is adjusted in accordance with the audio volume compensation information and output by the head unit 300.

As described above, the embodiments of the present disclosure may resolve a difference in volume of a Bluetooth audio stream between a mobile terminal and a head unit, and be effective in separately adjusting a volume to a value suitable for each mobile terminal. In addition, the embodiments of the present disclosure may be effective in resolving a difference in volume of a Bluetooth audio stream between a mobile terminal and a head unit by adjusting the volume to a value suitable for each mobile terminal through a volume control compensation scheme. Moreover, the embodiments of the present disclosure compensate for a default volume criterion based on a maximum volume criterion of a mobile terminal, and thus are effective in relatively easily overcoming a volume difference.

As described above, although the embodiments of the present disclosure have been described with reference to the accompanying drawings, it will be apparent to those skilled in the art that various modifications can be made in the present disclosure without departing from the technical spirit or essential features of the embodiments. Thus, the above-described embodiments are illustrative rather than restrictive in all aspects.

What is claimed is:

1. A head unit comprising:
a microcomputer storing last volume information corresponding to a finally adjusted volume of each of at least one mobile terminal,
wherein the microcomputer outputs an audio stream having a volume value adjusted based on the last volume information when a first paired mobile terminal of the at least one mobile terminal transmits the audio stream.

2. The head unit according to claim 1, wherein the microcomputer outputs the audio stream having the adjusted volume value by controlling an amplifier.

3. The head unit according to claim 1, wherein the microcomputer outputs the audio stream in real-time.

4. A method of adjusting an audio volume of a head unit, comprising:
storing, by a microcomputer, last volume information corresponding to a finally adjusted volume of each of at least one mobile terminal;
receiving, at the microcomputer, an audio stream transmitted from a first paired mobile terminal of the at least one mobile terminal;
adjusting a volume value of the received audio stream based on the stored last volume information; and
outputting, by the microcomputer, the audio stream having the adjusted volume value.

5. The method according to claim 4, wherein the outputting of the audio stream having the adjusted volume value comprises outputting the audio stream by the microcomputer controlling an amplifier.

6. The method according to claim 4, wherein the outputting of the audio stream having the adjusted volume value comprises outputting the audio stream in real-time by the microcomputer controlling an amplifier.

7. A non-transitory computer-readable recording medium for executing the method according to claim 4.

8. A head unit comprising:
a microcomputer storing a maximum audio volume value of at least one mobile terminal,
wherein the microcomputer compensates for a volume value of an audio stream transmitted from a first paired mobile terminal of the at least one mobile terminal based on the maximum audio volume value.

9. The head unit according to claim 8, wherein the microcomputer outputs audio volume information calculated by adding a volume compensation value obtained by the compensation for the volume value of the transmitted audio stream to the volume value of the audio stream.

10. The head unit according to claim 9, wherein the microcomputer outputs the audio volume information by controlling an amplifier.

11. The head unit according to claim 10, wherein the microcomputer outputs the audio volume information in real-time by controlling the amplifier.

12. A method of adjusting an audio volume of a head unit, comprising:
storing, by a microcomputer, a maximum audio volume value of at least one mobile terminal;
receiving, at the microcomputer, an audio stream transmitted from a first paired mobile terminal of the at least one mobile terminal;
compensating, by the microcomputer, for a volume value of the transmitted audio stream based on the stored maximum audio volume value; and
outputting, by the microcomputer, audio volume information obtained by the compensating for the volume value of the transmitted audio stream.

13. The method according to claim 12, wherein the compensating for the volume value of the audio stream comprises generating, by the microcomputer, the audio volume information calculated by adding a volume compensation value obtained by the compensation for the volume value of the audio stream to the volume value of the audio stream.

14. The method according to claim 13, wherein the outputting of the audio volume information comprises outputting the generated audio volume information by the microcomputer controlling an amplifier.

15. The method according to claim 14, wherein the outputting of the audio volume information comprises outputting the audio volume information in real-time by the microcomputer controlling the amplifier.

16. A non-transitory computer-readable recording medium for executing the method according to claim 12.

17. A head unit comprising:
a microcomputer storing a maximum audio volume value of at least one mobile terminal,
wherein the microcomputer generates audio volume compensation information by compensating for a volume value of an audio stream transmitted from a first paired mobile terminal of the at least one mobile terminal based on the maximum audio volume value, transmits the generated audio volume compensation information to the first mobile terminal, and then receives an audio stream adjusted based on the audio volume compensation information in response to the transmission of the audio stream.

18. The head unit according to claim 17, wherein the microcomputer transmits, to the first mobile terminal, the audio volume compensation information calculated by adding a volume compensation value obtained by the compensation for the volume value of the audio stream to the volume value of the audio stream.

19. The head unit according to claim 18, wherein the microcomputer outputs the audio stream by controlling an amplifier.

20. The head unit according to claim 19, wherein the microcomputer outputs the audio stream in real-time by controlling the amplifier.

21. A method of adjusting an audio volume of a head unit, comprising:
storing, by a microcomputer, a maximum audio volume value of at least one mobile terminal in a microcomputer;
receiving, at the microcomputer, an audio stream transmitted from a first paired mobile terminal of the at least one mobile terminal;
generating audio volume compensation information by compensating for a volume value of the audio stream based on the maximum audio volume value;
transmitting the generated audio volume compensation information to the first mobile terminal;
receiving, at the microcomputer, an audio stream adjusted based on the transmitted audio volume compensation information; and
outputting, by the microcomputer, the received audio stream.

22. The method according to claim 21, wherein the transmitting of the generated audio volume compensation information comprises transmitting, by the microcomputer, the audio volume compensation information calculated by adding a volume compensation value obtained by the compensation for the volume value of the audio stream to the volume value of the audio stream to the first mobile terminal.

23. The method according to claim 22, wherein the outputting comprises outputting the audio stream by the microcomputer controlling an amplifier.

24. The method according to claim 23, wherein the outputting comprises outputting the audio stream in real-time by the microcomputer controlling the amplifier.

25. A non-transitory computer-readable recording medium for executing the method according to claim 21.
